(19) United States
(12) Patent Application Publication
(10) Pub. No.: US 2008/0079127 A1
(43) Pub. Date: Apr. 3, 2008

(54) Pin Array No Lead Package and Assembly Method Thereof

(75) Inventor: Mark Allen Gerber, Lucas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/538,349

(22) Filed: Oct. 3, 2006

(51) Int. Cl. H01L 23/495

(52) U.S. Cl. 257/676

(57) ABSTRACT

A microelectronics package comprising: a die, a lead frame comprising: a substrate having a first side and a second side, an array of contacts positioned on the first side and the second side, and an aperture extending through the substrate between the contacts, wherein at least one contact is electrically coupled to the die, and a mold compound encapsulating the die and the substrate.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A MICROFICHE APPENDIX

Not applicable.

### FIELD

The present disclosure is directed generally to a package for a microelectronic device and a method of manufacturing the same. Specifically, the present disclosure is directed to a package that contains a lead frame with an array of contacts on both sides of a substrate and mold compound above and below the substrate, and a method for manufacturing the same.

### BACKGROUND

The manufacture of microelectronic devices is a long and complicated process. Generally, manufacture begins with a silicon wafer that undergoes various deposition, lithography, and etching processes to produce a plurality of semiconductor chips, commonly referred to as dies. The dies are then packaged, a process that includes attaching the dies to a lead frame and then encapsulating the dies and lead frame in a mold compound that protects the dies from damage or corrosion. After packaging, the devices are singulated. The devices can then be attached to a printed circuit board (PCB) or otherwise used as desired.

The packaging process presents many unique challenges. For example, manufacturers must stock numerous different lead frames because traditional lead frames are specific to the size and shape of the die. When a manufacturer changes from packaging one type of die to another type of die, the manufacturer must change the lead frame to match the size and shape of the new die. Thus, for a manufacturer that manufactures hundreds of different types of dies, the manufacturer must purchase and store hundreds of different lead frames. Purchasing and storing the various lead frames is cumbersome and increases the overall cost of manufacture. Consequently, a need exists for a universal lead frame that can be used with any size and shape of die.

### SUMMARY

In one aspect, the invention includes a lead frame comprising: a substrate having a first side and a second side, an array of contacts attached to the first side and the second side, and an aperture extending through the substrate between the contacts in the array.

The invention also includes a microelectronics package comprising: a die, a lead frame comprising: a substrate having a first side and a second side, an array of contacts positioned on the first side and the second side, and an aperture extending through the substrate between the contacts, wherein at least one contact is electrically coupled to the die, and a mold compound encapsulating the die and the substrate.

Finally, the invention includes a manufacturing process comprising: attaching a die to a lead frame comprising: a substrate having a first side and a second side, and an array of contacts positioned on the first side and the second side, encapsulating the die in a mold compound, and singulating the contacts such that at least one of the contacts is electrically isolated from the other contacts.

### BRIEF DESCRIPTION OF THE DRAWINGS

For a more complete understanding of the present disclosure and the advantages thereof, reference is now made to the following brief description, taken in connection with the accompanying drawings and detailed description, wherein like reference numerals represent like parts.

FIG. 1 is a bottom plan view of one embodiment of the package;

FIG. 2 is a section view of one embodiment of the package taken along line 2-2 in FIG. 1;

FIG. 3 is a bottom plan view of one embodiment of the lead frame;

FIG. 4 is a section view of one embodiment of the lead frame taken along line 4-4 in FIG. 3;

FIG. 5 is a section view of one embodiment of the lead frame taken along line 5-5 in FIG. 3;

FIG. 6 is a flowchart of one embodiment of the packaging process;

FIG. 7 is a section view of one embodiment of the tape application step of the packaging process;

FIG. 8 is a section view of one embodiment of the die attachment and electrical bonding steps of the packaging process;

FIG. 9 is a section view of one embodiment of the encapsulation step of the packaging process;

FIG. 10 is a section view of one embodiment of the tape removal step of the packaging process;

FIG. 11 is a section view of one embodiment of the lead singulation step of the packaging process;

FIG. 12 is a section view of one embodiment of the solder attachment step of the packaging process;

FIG. 13 is a top plan view of dies wire bonded to the lead frame; and

FIG. 14 is a top plan view of a PCB comprising the package described herein.

### DETAILED DESCRIPTION

It should be understood at the outset that although an exemplary implementation of one embodiment of the present disclosure is illustrated below, the present system may be implemented using any number of techniques, whether currently known or in existence. The present disclosure should in no way be limited to the exemplary implementations, drawings, and techniques illustrated below, including the exemplary design and implementation illustrated and described herein, but may be modified within the scope of the appended claims along with their full scope of equivalents.

The present application is related to U.S. patent application Ser. No. 11/050,086, filed Feb. 3, 2005, entitled “Method and Apparatus for Packaging an Electronic Chip”, by Gerber et al., which is incorporated herein by reference for all purposes.

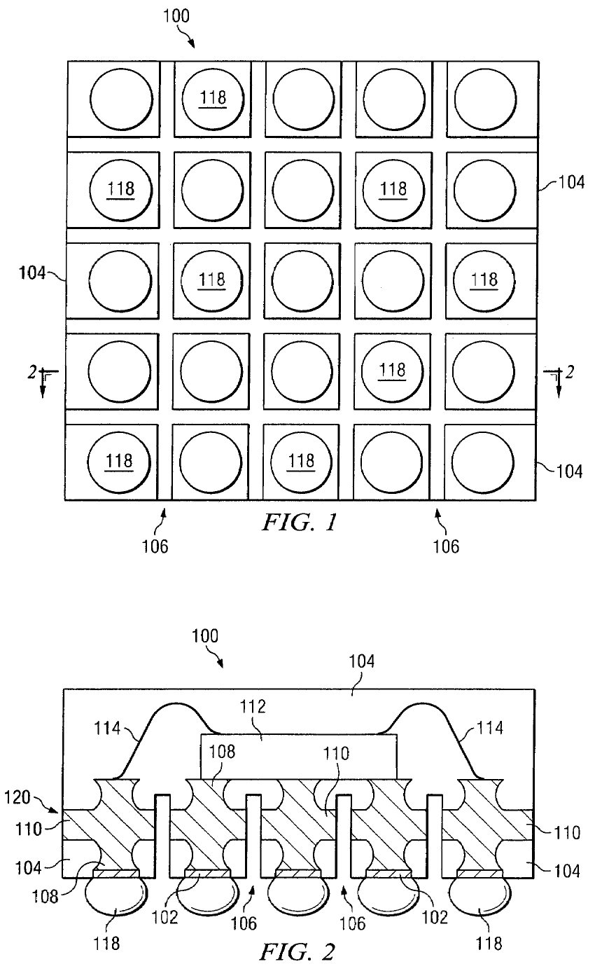

FIGS. 1 and 2 illustrate one embodiment of a microelectronic device package 100. The package 100 comprises a lead frame 120, a die 112, a plurality of wires 114 connecting the die 112 to the lead frame 120, and a mold compound 104 encapsulating the die 112, the wires 114, and the lead frame 120. The lead frame 120 comprises a substrate 110 and a plurality of contacts 108 separated by a plurality of grooves 106. The bottoms of the contacts 108 may be plated with a plating material 102 to increase their ability to bond with solder. In an embodiment, the package 100 also includes a solder ball 118 attached to each of the contacts 108. As explained in further detail below, the package 100 is advantageous because the substrate 110 contains an array of contacts 108 positioned on both sides of the substrate 110, which allows the same lead frame 120 to be used for various shapes and sizes of die. The package 100 is also advantageous because the mold compound 104 is positioned on both sides of the substrate 110, which substantially reduces the occurrence of warping. Finally, the package 100 configuration is advantageous because the mold compound 104 is positioned between the contacts 108, thereby substantially reducing the possibility of electrical shorts between nearby contacts 108, which allows the contacts 108 to be located closer to each other.

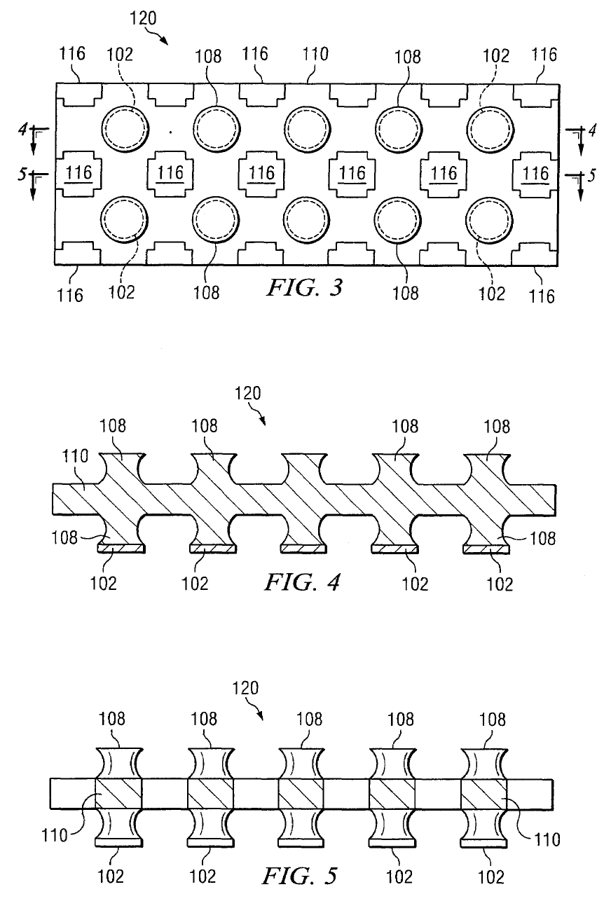

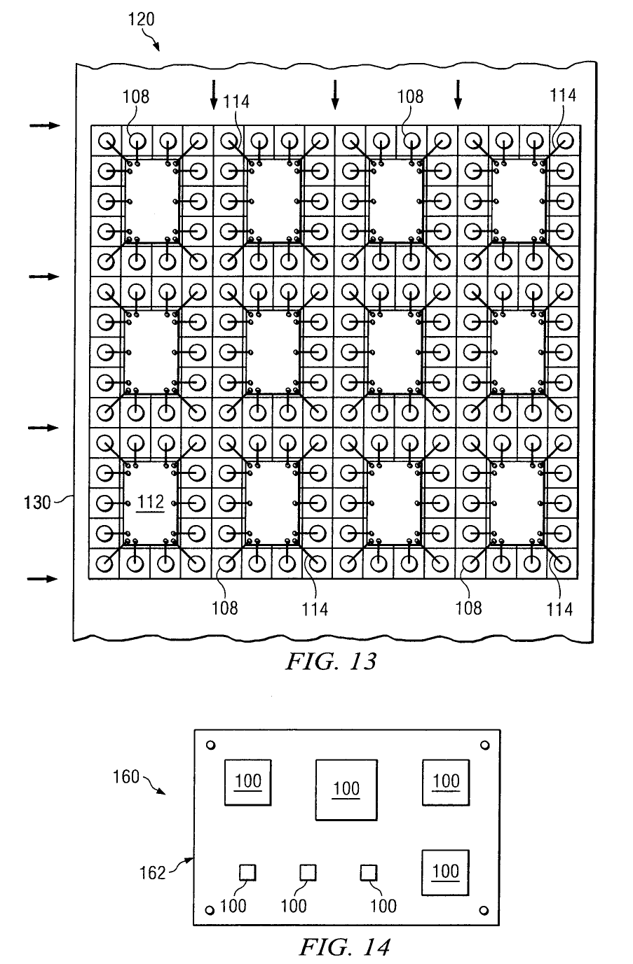

FIGS. 3, 4, and 5 illustrate one embodiment the lead frame 120, which comprises the contacts 108, the substrate 110, and at least one aperture 116. The contacts 108 are electrically conductive posts that connect the die 112 to the PCB, and are arranged in a two-dimensional array on both sides of the substrate 110. Specifically, the two-dimensional array of contacts 108 on one side of the substrate 110 may be used for attaching and connection dies and the two-dimensional array of contacts 108 on the other side of the substrate 110 may be used for attaching solder balls. The array of contacts 108 may occupy the entire surface of each side of the substrate 110, or may occupy less than the entire surface of each side of the substrate 110, such as 90 percent of the surface of the substrate 110. The contacts in the array have a pitch, which may be defined as the distance between the center points of two nearby contacts 108. As used herein, the term “universal pitch” means that the pitch between the contacts is constant or substantially the same throughout the lead frame 120, such that the array of contacts forms a grid-like pattern across the lead frame. An example of an array of contacts is found in U.S. patent application Ser. No. 11/050,086, filed Feb. 3, 2005, entitled “Method and Apparatus for Packaging an Electronic Chip”, by Gerber et al., which is incorporated herein by reference for all purposes. In contrast, conventional lead frames have been specifically designed for individual dies and did not contain an array of contacts on both sides of the substrate. For example, if a die is rectangular in shape and contains six contacts on each long side and four contacts on each short side for a total of twenty contacts, the lead frame would be designed with a repeating pattern of the twenty contacts and a central die pad. When a new shape, size, or configuration of die was designed (e.g. a larger die or a die with thirty contacts), the old lead frame could not be used for the new design. In contrast, when the lead frame has an array of contacts on both sides of the substrate, the same lead frame can be used for any shape, size, and configuration of die. Specifically, the array of contacts on both sides of the substrate allows the same lead frame to be used for any size, shape, or configuration of die because the contacts are not specifically configured for the size, shape, and configuration of the die. In addition, when the lead frame has an array of contacts on both sides of the substrate there is no need for a central die pad because one or more of the contacts serve as the die pad, as shown in FIGS. 12 and 13.

Returning to FIGS. 3, 4, and 5, in one embodiment the tops of the contacts 108 are square or rectangular, such that their surface area is maximized. Such an embodiment allows for greater support of the die 112 and larger connection tolerances when bonding the die 112 to the contacts 108. In another embodiment, the bottoms of the contacts 108 are round. Such an embodiment is advantages because it promotes the attachment of solder balls 118 onto the bottoms of the contacts 108. The substrate 110 is a planar piece of material that is used to hold the contacts 108 in place. Specifically, the substrate 110 keeps the contacts 108 connected yet physically separated from one another, such that the lead frame 120 can be picked up, moved, and otherwise handled as a single unit. While it is fully contemplated that the contacts 108 may be flush with the top, bottom, or both surfaces of the substrate 110, in an embodiment the contacts 108 are raised with respect to the top and bottom surfaces of the substrate 110. Such an embodiment is advantageous because it allows the mold compound 104 to be positioned above and below the substrate in relatively balanced amounts, which substantially reduces or eliminates the occurrence of warping. The top, bottom, or both sides of the contacts 108 may also be plated with the plating material 102 that is electrically conductive and allows solder to be attached to the contacts 108. Examples of suitable plating materials include nickel, palladium, tin, bismuth, silver, gold, and combinations thereof.

The aperture 116 is at least one hole in the substrate 110. The aperture 116 may be located along the perimeter of the substrate 110 such that the apertures 116 are not between the contacts 108, within the interior of the substrate 110 such that the apertures 116 are between the contacts 108, or any combination of the perimeter and the interior of the substrate 110. Further, a plurality of apertures 116 may be located between some or substantially all of the array of contacts 108. The use of the term “between the contacts” when describing the location of the apertures 116 includes locations directly between the contacts, as well as locations that are nearby locations that are directly between the contacts. The aperture 116 allows the mold compound 104 to be positioned on the bottom side of the substrate 110 during the encapsulation step described below. Specifically, the mold compound 104, which is generally injected above the substrate 110, may flow through the aperture 116 to a location underneath the substrate 110. The aperture 116 also allows the mold compound 104 on the top side of the substrate 110 to be connected to the mold compound 104 on the bottom surface of the substrate 110, such that substantially all of the mold compound 104 in the package 100 is continuously connected. In an embodiment, the apertures 116 make up from 10 percent to 90 percent of the total surface area of the substrate 110. In another embodiment, the apertures 116 make up from 25 percent to 75 percent of the total surface area of the substrate 110. In yet another embodiment, the apertures 116 make up from 40 percent to 60 percent of the total surface area of the substrate 110.

In some embodiments, the location, size, and shape of the apertures 116 are a consideration. When forming the apertures 116, it may be preferable to make the apertures 116 as large as possible to allow for increased mold flow during encapsulation, but not so large as to compromise the physical integrity of the substrate 110. Locating the centers of the apertures 116 at points furthest away from the centers of the contacts 108 is one method for increasing the size of the apertures 116. In addition, because it is not desirable for the apertures 116 to overlap the contacts 108, in one embodiment the overall width or diameter of each aperture 116 is determined by the manufacturing tolerances of the contacts 108. Furthermore, the aperture 116 area can be increased by using various aperture shapes, such as a circle, square, rectangle, triangle, hexagon, ellipse, diamond, and so forth. However, it has been found that the use of a cross-shaped aperture 116, such as the apertures 116 in FIG. 3, may be preferred in some embodiments to increase the area of each aperture 116 without compromising the other properties of the substrate 110.

The contacts 108 and substrate 110 may consist of an electrically conductive material, such as copper, aluminum, gold, silver, tin, or other metals. The specific chemical composition of the contacts 108 and substrate 110 may be selected based on the thermal expansion coefficient of the die 112, the mold compound 104, or both. Preferably, the substrate 110 is made of the same material as the contacts 108 such that the contacts 108 and substrate 110 are of unitary construction. In such an embodiment, the lead frame 120 can be manufactured by applying a mask or resist to the top and bottom surfaces of a piece of sheet metal in the places where the contacts 108 are desired, etching the sheet metal to produce the contacts 108, and then punching or etching the apertures 116 out of the substrate 110 in the desired locations. Manufacturing such a lead frame 120 is advantageous because it is simple and inexpensive. In addition, such a lead frame 120 is advantageous because the substrate 110 electrically couples the contacts 108 together, which allows the contacts 108 to be selectively singulated such that some of the contacts 108 remain electrically coupled. Using the lead frame 120 is also preferable because it eliminates the need for a final etch step to expose the bottoms of the contacts 108, a necessary step in some prior packages. Alternatively, the substrate 110 may consist of an electrically insulating material, while the contacts 108 consist of an electrically conductive material. Such an embodiment is advantageous because the substrate 110 electrically insulates the contacts 108 from each other, and thus there is no need to singulate the contacts 108.

Returning to FIGS. 1 and 2, in an embodiment the package 100 further comprises the die 112. The die 112 is an integrated circuit that is comprised of a layer of semiconductor material, such as silicon, and a plurality of electronic devices attached to or embedded in the semiconductor material. Generally, the die 112 comprises an active portion and a plurality of bond pads (not shown). The active portion performs computations and other functions and may include numerous N-type or P-type metal oxide semiconductor (MOS) devices. The active portion may also include other devices and structures such as micro-electro-mechanical (MEMS) device. Bond pads are points where the die 112 electrically couples to the lead frame 120. The bond pads are typically located on an outer portion of the die 112, but may be located near the center portion of the die 112. In some embodiments, the die 112 may be comprised of a plurality of individual integrated circuits stacked together.

In an embodiment, the package 100 further comprises the wires 114. The wires 114 electrically couple the die 112 to the lead frame 120. Specifically, the wires 114 couple the bond pads on the die 112 to the top surface of the contacts 108 on the lead frame 120. The wires 114 may be made of any electrically conductive material, including gold, silver, copper, aluminum, and alloys thereof. Of course, the die 112 may be attached to the contacts 108 using other bonding methods, including the BGA or direct solder of the bond pads to the contacts 108.

In an embodiment, the package 100 further comprises the mold compound 104. The mold compound 104 protects the die 112, the wires 114, and most of the lead frame 120 from damage or corrosion. The mold compound 104 may include materials such as epoxy, plastic, or other material adapted for protecting the die 112, the wires 114, or the lead frame 120. In an embodiment, the mold compound 104 may include epoxy resins, phenolic hardeners, silicas, catalysts, pigments, mold release agents, or other compounds. Alternatively, the mold compound 104 may include multiple parts, such as a ceramic header and a top cap attached over the header to protect a mounted device. The mold compound 104 is generally positioned around the die 112, wires 114, and lead frame 120 in liquid form and allowed to harden into a solid mass.

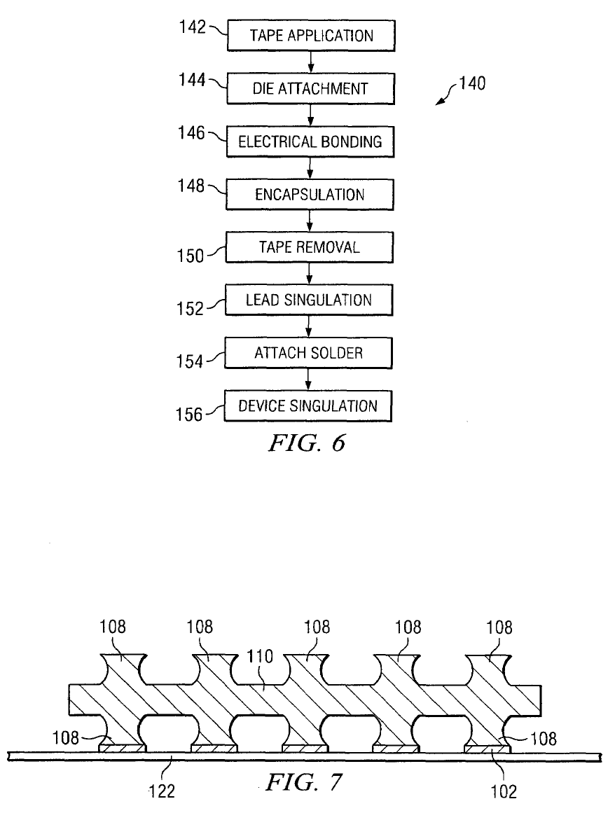

In an embodiment, the microelectronic device is packaged according to a packaging process, illustrated in FIG. 6. The process 140 generally comprises the steps of: applying a tape to the lead frame at 142, attaching the die to the lead frame at 144, electrically bonding the die to the lead frame at 146, encapsulating the die, wires, and lead frame at 148, removing the tape from the package at 150, singulating the contacts at 152, attaching the solder to the package at 154, and singulating the packages 100 at 156. Each of the aforementioned steps is described in greater detail below.

In an embodiment, the process 140 comprises the step of applying the tape 122 to the lead frame 120 at 142, as illustrated in FIG. 7. The tape 122 is a polymer film or other type of material that prevents the mold compound 104 from covering the bottoms of the contacts 108 during encapsulation. Alternatively, a layer of silicone or a grommet can be used in lieu of the tape 112. Specifically, the bottoms of the contacts 108 may be placed on the flat surface of the layer of silicone or the grommet may be temporarily attached to the bottoms of the contacts 108 such that mold compound 104 does not attach to the bottoms of the contacts 108 during encapsulation. Generally, the tape 122 contains an adhesive on its upper surface such that the tape sticks to the bottoms of the contacts 108. Alternatively, the tape 122 can be configured without an adhesive such that the lead frame 120 merely rests on top of the tape 122. The tape 122 allows the mold compound 104 to surround the bottoms of the contacts 108 during encapsulation but prevents the mold compound 104 from covering the bottoms of the contacts 108. Such a configuration substantially reduces or eliminates the occurrence of mold flash, a condition that occurs when the mold compound 104 covers the bottom surface of the contacts 108. Further, the tape 122 allows the mold compound 104 to form a flush surface with the bottoms of the contacts 108, such that the bottom side of the package 100 is substantially smooth.

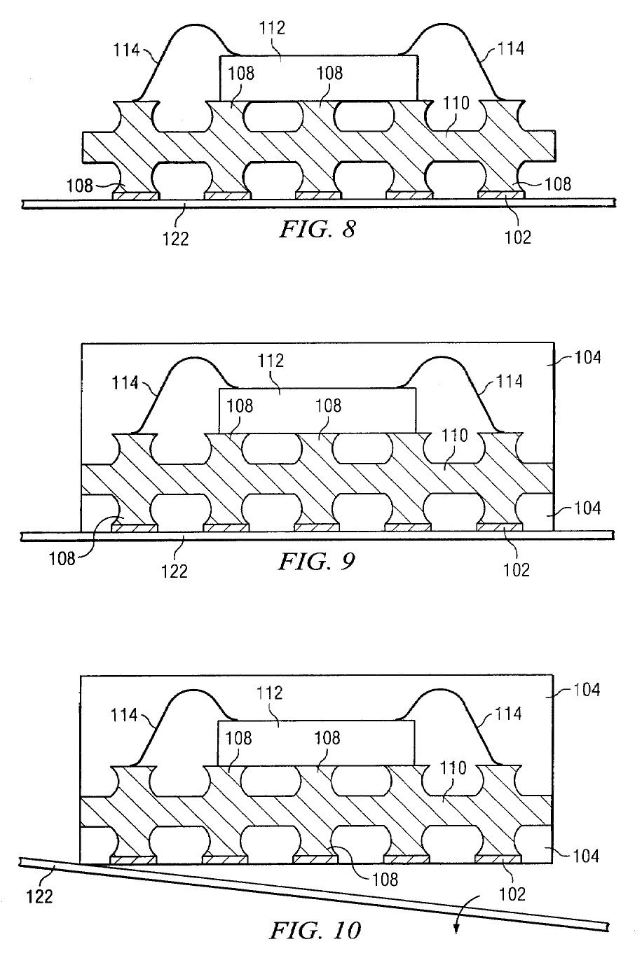

In an embodiment, the process 140 comprises the step of attaching the die 112 to the lead frame 120 at 144, as illustrated in FIG. 8. The die 112 may be attached to the lead frame 120 by a thermally or electrically conductive die attachment compound, such as silver epoxy. Some of the die attachment compound may pass through one or more of the apertures 116 and be apparent on the bottom of the package 100. Such a presence of die attachment compound may be preferable because the die attachment compound tends to improve the thermal conductivity of the package 100. Alternatively, the die 112 can be attached to the lead frame 120 using a film. Generally, the die 112 is attached to one or more of the contacts 108 that are not used as electrical connections. However, in some embodiments, the contacts 108 onto which the die 112 is mounted may be used as an electrical connection, most commonly the ground. The use of electrically conductive die attachment compounds is preferred in such a configuration.

In an embodiment, the process 140 comprises the step of bonding the die 112 to the lead frame 120 at 146, also illustrated in FIG. 8. The die 112 contains a plurality of bond sites (not shown) on its upper side that need to be electrically coupled to the top surfaces of the contacts 108 so that the package 100 can be connected to the PCB. One method of electrically bonding the die 112 to the contacts 108 is to solder or weld wires 114 between the die bond sites and the contacts 108. Wire bonding methods are well known within the art and need not be explained in detail here. Alternatively, the die 112 may be electrically bonded using another bonding method, such as die stacking, direct bonding, or flip bonding. Persons of ordinary skill in the art are aware of electrical bonding methods such as these and other methods.

In an embodiment, the process 140 comprises the step of encapsulating the die 112, the wires 114, and the lead frame 120 at 148, as illustrated in FIG. 9. A mold or mold press may be employed to form the mold compound 104 around the die 112, the wires 114, and the lead frame 120. The encapsulation method may be any encapsulation method, including liquid compression molding (LCM), cavity direct injection molding (CDIM), and transfer molding. These encapsulation methods typically surround the die 112, the wires 114, and the lead frame 120 with a liquid or semi-solid mold compound 104, and allow the mold compound 104 to harden into a sold mass.

In an embodiment, the process 140 comprises the step of removing the tape 122 from the package 100 at 150, as illustrated in FIG. 10. The tape 122 may be peeled, cut, etched, stripped, or otherwise removed from the package 100 using any method. If a silicone sheet or grommet is used instead of the tape 122, then the package 100 may simply be picked up off of the silicone sheet or grommet to separate the package 100 from the silicone sheet or grommet. Persons of ordinary skill in the art are aware of other methods for removing the tape 122 from the package 100.

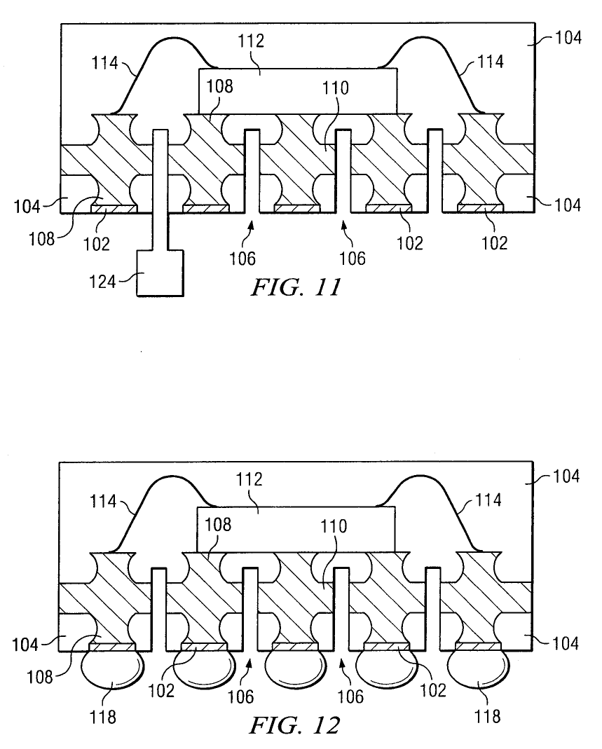

In an embodiment, the process 140 comprises the step of singulating the contacts 108 at 152, as illustrated in FIG. 11. The singulation step comprises cutting the substrate 110 between the individual contacts 108 to sever the electrical connection between the contacts 108, thereby forming the cavities 106. The contacts 108 may be singulated with a laser, saw, or any other cutting apparatus known to a person of ordinary skill in the art. Alternatively, etchants such as corrosive or ionic liquids and gases, may be used to singulate the contacts 108. While it is generally considered easier and quicker to singulate each contact 108 from the remaining contacts 108, it is also anticipated that the singulation of the contacts 108 can be selective so that the majority of the contacts 108 are singulated, but specific contacts 108 are not singulated. Such an embodiment may be preferable when it is desirable to have multiple contacts that are electrically connected, such as an electrical ground. The singulation step may also include a cleaning step in which compressed air, a brush, or some other tool is swept through the cavities 106. The cleaning step ensures that there are no metal burrs or other particles that could cause shorting between the singulated contacts 108.

In an embodiment, the process 140 optionally comprises the step of attaching solder to the contacts 108 at 154, as illustrated in FIG. 12. In one embodiment, the solder is solder balls 118, which are spherical drops of solder that allow the package 100 to be attached to the PCB during the solder reflow process. The solder balls 118 are typically attached to the package 100 by first applying a flux to the contacts 108, and then applying the solder balls 118 to the contacts 108. The flux helps the solder balls 118 stick to the contacts 108. Alternatively, the solder can be a solder paste, which is typically a mix of solder and flux that is screened onto the bottom of the package 100 using a solder mask. Other types of solder attachment methods can be used, if desired.

After the manufacturing of the packages 100 is complete, the packages 100 are singulated from the other packages 100 and the remainder of the lead frame 120 at 156. Much like the contact singulation step described above, the singulation of the packages 100 uses a laser, saw, etch, or other cutting device to cut the individual packages 100 apart. FIG. 13 illustrates a plurality of packages 100 configured on a single lead frame 120, but shown without the mold compound 104 so that the location of the individual die 112 can be seen. The lead frame 120 shown in FIG. 13 is one of a plurality of lead frames 120 contained on a metal strip 130. During the package singulation step, the individual packages 100 are cut apart from the other packages 100, the remainder of the lead frame 120, and the strip 130 along the lines depicted by the five horizontal arrows along the left side of the lead frame 120 and the five vertical arrows along the top side of the lead frame 120. The cut extends through the entire lead frame 120 as well as the mold compound 104 such that the individual packages 100 are completely separated from each other. The individual packages 100 can then be attached to a PCB or otherwise used as desired.

There are several advantages to the package 100 described herein. The package 100 contains an array of contacts 108 on both sides of the substrate 110. The array of contacts allows the same lead frame 120 to be used for various types of die 112. For example, when a manufacturer implements the lead frame 120 and switches from packaging one type of die 112 to packaging a different type of die 112, there is no need to change lead frames 120. Thus, the manufacturer does not need to store hundreds of different types of lead frames 120, but can instead store and use a single lead frame 120. The single type of lead frame 120 allows the manufacturer to realize substantially reduced tooling costs for lead frame manufacturing, which reduces the overall cost of manufacturing the devices.

The package 100 described herein may have further advantages because the mold compound 104 is positioned on both sides of the substrate 110. Having mold compound 104 above and below the lead frame 120 reduces the occurrence of warping. Warping occurs when there is an unbalanced amount of mold compound 104 on one side of the package 100. Specifically, when prior packages cooled after the molding process, the prior packages tended to warp because the mold compound 104 and the lead frame 120 have different thermal expansion coefficients. When the present package 100 is implemented, the presence of mold compound 104 on both sides of the lead frame 120 substantially reduces or may eliminate the warping, thereby improving the quality and acceptance rate of the devices.

The package 100 configuration described herein may have further advantages because the mold compound 104 is positioned between the contacts 108. Having the mold compound 104 on the top and bottom sides of the substrate 110 allows the saw to produce fewer burs when the substrate 110 is singulated. Thus, the mold compound 104 substantially reduces the possibility of electrical shorts between the contacts 108 caused by burs and solder from the contact and package singulation processes. The presence of electrically insulating mold compound 104 between the contacts 108 also allows the contacts 108 to be located closer to each other because there is a reduced likelihood of arcing between the contacts 108. Positioning the mold compound 104 between the contacts 108 also leads to increased saw life. Specifically, because the saw does not cut any solder and cuts more mold compound 104 than lead frame 120, the saw blades tend to last longer, leading to increased productivity and reduced expense. Also, when all of the contacts 108 are singulated, the mold compound 104 holds the contacts in place after singulation. The mold compound is particularly successful at holding the contacts in place because the mold compound is continuous throughout the package and the singulation removes the structural connection between the contacts.

The microelectronic device package 100 described above may be employed on any general-purpose substrate having electrical contacts and interconnects suitable for integrating electronic devices and components. FIG. 14 illustrates a typical, general-purpose PCB 160 suitable for implementing one or more embodiments disclosed herein. The PCB 160 includes a printed substrate 162 and a plurality of packages 100. The substrate 162 may be rigid or flexible and may include multiple layers of insulating material and conductive interconnects. The packages 100 are attached to the substrate 162, for example by solder. The substrate 162 may also include other electrical components, such as resistors, capacitors, inductors, thyristors, fuses (i.e., over-current or over-voltage protection devices), or other small component devices. In an embodiment, the PCB 160 may be employed in for example a mobile electronic device such as a mobile phone or personnel data assistant (PDA). In other embodiments, the PCB 160 may be employed in electrical components employed in automotive vehicles where the PCB 160 may be subjected to a significant amount of thermal stress. Of course, the PCB 160 or the packages 100 may be employed in other electronic devices such as computers, networking equipment such as wireless routers, mobile audio devices, or any other devices.

Persons of ordinary skill in the art will appreciate that the figures merely illustrate one embodiment of the package and should not be used to limit the present disclosure. For example, while only a limited number of contacts are illustrated in the figures, a person of ordinary skill in the art will appreciate that the package may be configured with any number or contacts, the number of which is generally dictated by the packaging type. Specific examples of suitable package types include: a quad flat no lead package (QFN) and a pin array no lead package (PAN). Persons of ordinary skill in the art are aware of other packaging specifications created by the Joint Electron Device Engineering Council (JEDEC) and other standards organizations.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein, but may be modified within the scope of the appended claims along with their full scope of equivalents. For example, the various elements or components may be combined or integrated in another system or certain features may be omitted, or not implemented. In addition, the reference to any material being above or below another material is specific to the associated figure and is meant to include a similar configuration arranged in another (i.e. inverted) orientation.

Also, techniques, systems, subsystems and methods described and illustrated in the various embodiments as discrete or separate may be combined or integrated with other systems, modules, techniques, or methods without departing from the scope of the present disclosure. Other items shown or discussed as directly coupled or communicating with each other may be coupled through some interface or device, such that the items may no longer be considered directly coupled to each other but may still be indirectly coupled and in communication, whether electrically, mechanically, or otherwise with one another. Other examples of changes, substitutions, and alterations are ascertainable by one skilled in the art and could be made without departing from the spirit and scope disclosed herein.

What is claimed is:

1. A lead frame comprising:
a substrate having a first side and a second side;
an array of contacts attached to the first side and the second side; and
an aperture extending through the substrate between the contacts in the array.

2. The lead frame of claim 1 wherein the contacts extend above and below the surface of the substrate.

3. The lead frame of claim 1 wherein the contacts on the first side are round and the contacts on the second side are square.

4. The lead frame of claim 1 wherein the aperture is one of a plurality of apertures and the apertures comprise from 25 percent to 75 percent of the substrate surface area.

5. The lead frame of claim 1 wherein the aperture is cross-shaped.

6. A microelectronics package comprising:
a die;
a lead frame comprising: a substrate having a first side and a second side, an array of contacts positioned on the first side and the second side, and an aperture extending through the substrate between the contacts, wherein at least one contact is electrically coupled to the die; and
a mold compound encapsulating the die and the substrate.

7. The package of claim 6 wherein some of the mold compound is positioned above the substrate and some of the mold compound is positioned below the substrate.

8. The package of claim 6 wherein some of the mold compound is positioned between the contacts and within the aperture.

9. The package of claim 6 wherein the contacts have been singulated such that at least one of the contacts is electrically isolated from the other contacts.

10. The package of claim 6 wherein the substrate further comprises an aperture.

11. The package of claim 10 wherein the aperture is located on the perimeter of the substrate.

12. The package of claim 10 wherein the aperture is located on the interior of the substrate.

13. The package of claim 10 wherein the mold compound above the substrate is connected to the mold compound below the substrate via mold compound in the aperture.

14. The package of claim 10 further comprising: a printed circuit board, wherein the die, the lead frame, and the mold compound comprise a microelectronic device that is provided on the printed circuit board.

15. A manufacturing process comprising:
attaching a die to a lead frame comprising: a substrate having a first side and a second side, and an array of contacts located on the first side and the second side;
encapsulating the die in a mold compound; and
singulating the contacts such that at least one of the contacts is electrically isolated from the other contacts.

16. The process of claim 15 further comprising: applying a tape to the bottom surface of the contacts.

17. The process of claim 15 further comprising: electrically coupling the die to one of the contacts.

18. The process of claim 15 further comprising: removing a tape from the bottom surface of the contacts.

19. The process of claim 15 wherein at least some of the mold compound is located between the contacts.

20. The process of claim 15 wherein the substrate comprises an aperture between each of the contacts.
